(19) United States
(12) Patent Application Publication
(10) Pub. No.: US 2020/0387068 A1
(43) Pub. Date: Dec. 10, 2020

(54) RADIATION-SENSITIVE COMPOSITION, PATTERN-FORMING METHOD AND COMPOUND

(71) Applicants: JSR CORPORATION, Tokyo (JP); CORNELL UNIVERSITY, Ithaca, NY (US)

(72) Inventors: Kazunori Sakai, Tokyo (JP); Christopher K. Ober, Ithaca, NY (US)

(73) Assignees: JSR CORPORATION, Tokyo (JP); CORNELL UNIVERSITY, Ithaca, NY (US)

(21) Appl. No.: 16/893,601

(22) Filed: Jun. 5, 2020

Related U.S. Application Data
(60) Provisional application No. 62/857,405, filed on Jun. 5, 2019.

(51) Int. Cl. G03F 7/004

(52) U.S. Cl. CPC G03F 7/0042; G03F 7/0045

(57) ABSTRACT

A radiation-sensitive composition including: a compound having a metal atom and a ligand; and a solvent. The ligand is derived from a first compound represented by the following formula (1), a second compound represented by the following formula (2), or a combination thereof. In the following formula (1), X¹ represents a substituted or unsubstituted ethenyl group or a substituted or unsubstituted ethynyl group; Y¹ represents —NR^{A}R^{B} or —COOH. In the following formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; and Y² represents —NR^{A}R^{B} or —COOH.

X¹—R¹-Y¹ (1)

X²—CHR³—R²—Y² (2)

### CROSS-REFERENCE TO RELATED APPLICATIONS

The present application is based on and claims the benefits of priority to U.S. Provisional Patent Application No. 62/857,405, filed Jun. 5, 2019. The contents of the application are incorporated herein by reference in their entirety.

### BACKGROUND OF THE INVENTION

### Field of Invention

The present invention relates to a radiation-sensitive composition, a pattern-forming method, and a compound.

A typical radiation-sensitive composition for use in microfabrication by lithography generates an acid by exposure to an electromagnetic wave such as a far ultraviolet ray (e.g., an ArF excimer laser beam, a KrF excimer laser beam, etc.) or an extreme ultraviolet ray, a charged particle ray such as an electron beam, or the like at a light-exposed region. A chemical reaction in which the acid serves as a catalyst causes a difference in rates of dissolution in a developer solution between light-exposed regions and light-unexposed regions to form a pattern on a substrate. The pattern thus formed can be used as a mask or the like in substrate processing.

Miniaturization in processing techniques has progressed with desirability for improved resist performance of such radiation-sensitive compositions. Researches have been done on the types, molecular structures and the like of polymers, acid generating agents and other components to be used in a composition, and combinations thereof (refer to Japanese Unexamined Patent Application, Publication Nos. H11-125907, H8-146610, and 2000-298347).

### SUMMARY OF THE INVENTION

According to an aspect of the present invention, a radiation-sensitive composition includes a compound including a metal atom and a ligand, and a solvent. The ligand is derived from a first compound represented by formula (1), a second compound represented by formula (2), or a combination thereof.

X¹—R¹—Y¹ (1)

X²—CHR³—R²—Y² (2)

In the formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; and R¹ represents a single bond or a divalent organic group having 1 to 20 carbon atoms in a case in which Y¹ represents —NR^{A}R^{B}, or R¹ represents a divalent organic group having 1 to 20 carbon atoms in a case in which Y¹ represents —COOH, and

in the formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.

According to another aspect of the present invention, a radiation-sensitive composition includes a compound obtained by blending a metal-containing compound and an organic compound, and a solvent. The organic compound is a first compound represented by formula (1), a second compound represented by formula (2), or a combination thereof.

X¹—R¹—Y¹ (1)

X²—CHR³—R²—Y² (2)

In the formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; and R¹ represents a single bond or a divalent organic group having 1 to 20 carbon atoms in a case in which Y¹ represents —NR^{A}R^{B}, or R¹ represents a divalent organic group having 1 to 20 carbon atoms in a case in which Y¹ represents —COOH, and

in the formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.

According to still another aspect of the present invention, a radiation-sensitive composition includes a first compound represented by formula (1), a second compound represented by formula (2), or a combination thereof, a compound comprising a metal atom, and a solvent.

X¹—R¹—Y¹ (1)

X²—CHR³—R²—Y² (2)

In the formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; and R¹ represents a single bond or a divalent organic group having 1 to 20 carbon atoms in a case in which Y¹ represents —NR^{A}R^{B}, or R¹ represents a divalent organic group having 1 to 20 carbon atoms in a case in which Y¹ represents —COOH, and

in the formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.

### DESCRIPTION OF THE EMBODIMENTS

For a radiation-sensitive composition, improving sensitivity to, in particular, an extreme ultraviolet ray or an electron beam is desired, and use of a complex including a metal atom as a component of the radiation-sensitive composition has been studied. It is considered that such a complex absorbs an extreme ultraviolet ray or the like to generate a secondary electron, and an action of this secondary electron promotes generation of an acid from an acid generating agent or the like, thereby enabling sensitivity to be improved.

However, the radiation-sensitive composition in which such a complex is used is disadvantageous in terms of poor resolution, and the sensitivity is still unsatisfactory.

The present invention provides in some aspects a radiation-sensitive composition superior in resolution and sensitivity, a pattern-forming method, and a compound.

According to an aspect of the invention, a radiation-sensitive composition (hereinafter, may be also referred to as “radiation-sensitive composition (I)”) contains: a compound (hereinafter, may be also referred to as “(A1) compound” or “compound (A1)”) having a metal atom (hereinafter, may be also referred to as “metal atom (M)”) and a ligand (hereinafter, may be also referred to as “ligand (L)”); and a solvent (hereinafter, may be also referred to as “(B) solvent” or “solvent (B)”), wherein the ligand (L) is derived from a first compound (hereinafter, may be also referred to as “compound (i)”) represented by the following formula (1), a second compound (hereinafter, may be also referred to as “compound (ii)”) represented by the following formula (2), or a combination thereof,

X¹—R¹—Y¹ (1)

X²—CHR³—R²—Y² (2)

wherein,

in the formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; and R¹ represents a single bond or a divalent organic group having 1 to 20 carbon atoms in a case in which Y represents —NR^{A}R, or R¹ represents a divalent organic group having 1 to 20 carbon atoms in a case in which Y¹ represents —COOH, and

in the formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.

According to another aspect of the invention, a radiation-sensitive composition (hereinafter, may be also referred to as “radiation-sensitive composition (II)”) contains: a compound (hereinafter, may be also referred to as “(A2) compound” or “compound (A2)”) obtained by blending a metal-containing compound (hereinafter, may be also referred to as “(W) metal-containing compound” or “metal-containing compound (W)”) and an organic compound (hereinafter, may be also referred to as “(S) organic compound” or “organic compound (S)”); and a solvent ((B) solvent), wherein the organic compound (S) is the compound (i), the compound (ii) or a combination thereof.

According to still another aspect of the invention, a radiation-sensitive composition (hereinafter, may be also referred to as “radiation-sensitive composition (III)”) contains: the compound (i), the compound (ii) or a combination thereof (hereinafter, may be also referred to as “(S) compound” or “compound (S)”); a compound (hereinafter, may be also referred to as “(W) compound” or “compound (W)”) having a metal atom; and a solvent ((B) solvent).

According to yet another aspect of the invention, a pattern-forming method includes: applying the radiation-sensitive composition of the embodiment of the present invention directly or indirectly on a substrate; exposing a film formed by the applying; and developing the film exposed.

According to a further aspect of the invention, a compound has: the metal atom (M); and the ligand (L) derived from the compound (i), the compound (ii), or a combination thereof.

The radiation-sensitive composition and the pattern-forming method according to the aspects of the present invention enable a pattern having high resolution to be formed, with high sensitivity. The compound according to the aspect of the present invention can be suitably used as a component of the radiation-sensitive composition. Therefore, these can be suitably used for formation of fine resist patterns in lithography steps of various types of electronic devices such as semiconductor devices and liquid crystal devices for which further progress of miniaturization is expected in the future.

### Radiation-Sensitive Composition

The radiation-sensitive composition according to an embodiment of the present invention includes the following modes:

the radiation-sensitive composition (I): containing the compound (A1) and the solvent (B);

the radiation-sensitive composition (II): containing the compound (A2) and the solvent (B); and

the radiation-sensitive composition (III): containing the compound (S), the compound (W), and the solvent (B).

Hereinafter, the radiation-sensitive compositions (I) to (III) may be also merely referred to as “compositions (I) to (III)”, and the compound (A1) and the compound (A2) may be also referred to as “(A) compound” or “compound (A)” in combination.

The radiation-sensitive composition according to the embodiment of the invention is superior in resolution and sensitivity due to containing the compound (A) and the solvent (B). Although not necessarily clarified and without wishing to be bound by any theory, the reason for achieving the effects described above due to the radiation-sensitive composition having the aforementioned constitution may be supposed as in the following, for example. It is considered that when the ligand (L) is derived from the compound (i), crosslinking in the compound (A) can occur upon the exposure by the ethenyl group or the ethynyl group represented by X¹ in the formula (1), and thus insolubilization is further accelerated. In addition, it is believed that when the ligand (L) is derived from the compound (ii), a hydrogen atom bonding to the carbon atom adjacent to X² in the formula (2) in the compound (A) becomes more likely to be dissociated, thereby enabling a proton to be given. As a result, resolution and sensitivity of the radiation-sensitive composition according to the embodiment of the invention are improved.

The compositions (I) to (III) will be described below.

### Composition (I)

The composition (1) contains the compound (A1) and the solvent (B). The composition (I) may also contain, as a favorable component, a radiation-sensitive acid generating agent (hereinafter, may be also referred to as “(C) acid generating agent” or “acid generating agent (C)”), and may further contain other optional component(s) within a range not leading to impairment of the effects of embodiments of the present invention.

Each component will be described in the following.

(A1) Compound

The compound (A1) has the metal atom (M) and the ligand (L).

Metal Atom (M)

The metal atom (M) is exemplified by metal atoms from groups 3 to 6 in periodic table, and the like. The compound (A1) may have one, or two or more types of the metal atom (M).

Examples of the metal atoms from group 3 include a scandium atom, an yttrium atom, a lanthanum atom, a cerium atom and the like.

Examples of the metal atoms from group 4 include a titanium atom, a zirconium atom, a hafnium atom and the like.

Examples of the metal atoms from group 5 include a vanadium atom, a niobium atom, a tantalum atom and the like.

Examples of the metal atoms from group 6 include a chromium atom, a molybdenum atom, a tungsten atom and the like.

Examples of the metal atoms from group 7 include a manganese atom, a rhenium atom and the like.

Examples of the metal atoms from group 8 include an iron atom, a ruthenium atom, an osmium atom and the like.

Examples of the metal atoms from group 9 include a cobalt atom, a rhodium atom, an iridium atom and the like.

Examples of the metal atoms from group 10 include a nickel atom, a palladium atom, a platinum atom and the like.

Examples of the metal atoms from group 11 include a copper atom, a silver atom, a gold atom and the like.

Examples of the metal atoms from group 12 include a zinc atom, a cadmium atom, a mercury atom and the like.

Examples of the metal atoms from group 13 include an aluminum atom, a gallium atom, an indium atom and the like.

Examples of the metal atoms from group 14 include a germanium atom, a tin atom, a lead atom and the like.

Examples of the metal atoms from group 15 include an antimony atom, a bismuth atom and the like.

Examples of the metal atoms from group 16 include a tellurium atom and the like.

The metal atom (M) is preferably the metal atoms from groups 4 to 13, more preferably the metal atoms from groups 8 to 12, still more preferably the metal atoms from group 9, group 10 or group 12, and particularly preferably cobalt, nickel or zinc.

The compound (A1) may also have in addition to the metal atom (M), for example, a metalloid atom such as boron or silicon. In the case in which the compound (A1) includes the metalloid atom, the proportion (% by mass) of the metalloid atom contained in the compound (A1) is typically less than the proportion of the metal atom (M) contained therein.

Ligand (L)

The ligand (L) is derived from at least one (hereinafter, may be also referred to as “compound (S)”) selected from the group consisting of the compound (i) and the compound (ii). The compound (S) is exemplified by a carboxylic acid having —COOH (hereinafter, may be also referred to as “carboxylic acid (X)”), a nitrogen-containing compound having —NR^{A}R^{B} (hereinafter, may be also referred to as “nitrogen-containing compound (Z)”), and the like.

The ligand (L) (hereinafter, may be also referred to as “ligand (L-X)”) derived from the carboxylic acid (X) typically coordinates to the metal atom (M) by the oxygen atom in —COOH or —COO— yielded by anionization of —COOH. The ligand (L) (hereinafter, may be also referred to as “ligand (L-Z)”) derived from the nitrogen-containing compound (Z) typically coordinates to the metal atom (M) by the nitrogen atom in —NR^{A}R^{B}.

The compound (i) and the compound (ii) will be described in the following.

Compound (i)

The compound (i) is represented by the following formula (1).

X¹—R¹—Y¹ (1)

In the above formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R¹ represents a single bond or a divalent organic group having 1 to 20 carbon atoms in a case in which Y¹ represents —NR^{A}R^{B}, or R¹ represents a divalent organic group having 1 to 20 carbon atoms in a case in which Y¹ represents —COOH.

The compound (i) is exemplified by the carboxylic acid (X) in which Y¹ represents —COOH (hereinafter, may be also referred to as “carboxylic acid (i-X)”), the nitrogen-containing compound (Z) in which Y¹ represents —NR^{A}R^{B} (hereinafter, may be also referred to as “nitrogen-containing compound (i-Z)”), and the like.

Examples of a substituent which may substitute for the hydrogen atom of the ethenyl group or the ethynyl group represented by X¹ include alkyl groups having 1 to 10 carbon atoms such as a methyl group and an ethyl group, and the like.

X¹ represents preferably an alkyl group-substituted or unsubstituted ethenyl group or an unsubstituted ethynyl group, and more preferably a methyl group-substituted or unsubstituted ethenyl group or an unsubstituted ethynyl group.

The “organic group” as referred to herein means a group that includes at least one carbon atom. The monovalent organic group having 1 to 20 carbon atoms which may be represented by R^{A} or R^{B} is exemplified by: a monovalent hydrocarbon group having 1 to 20 carbon atoms; a group that includes a divalent hetero atom-containing group between two adjacent carbon atoms of the monovalent hydrocarbon group having 1 to 20 carbon atoms; a group obtained by substituting with a monovalent hetero atom-containing group a part or all of hydrogen atoms included in the monovalent hydrocarbon group having 1 to 20 carbon atoms or the group that includes a divalent hetero atom-containing group; and the like.

The “hydrocarbon group” is exemplified by a chain hydrocarbon group, an alicyclic hydrocarbon group, and an aromatic hydrocarbon group. The “hydrocarbon group” may be either a saturated hydrocarbon group or an unsaturated hydrocarbon group. The “chain hydrocarbon group” as referred to herein means a hydrocarbon group not having a ring structure and being constituted from only a chain structure, and may be exemplified by a linear hydrocarbon group and a branched hydrocarbon group. The “alicyclic hydrocarbon group” as referred to herein means a hydrocarbon group having only an alicyclic structure as a ring structure and not having an aromatic ring structure, and may be exemplified by a monocyclic alicyclic hydrocarbon group and a polycyclic alicyclic hydrocarbon group, wherein it is not necessary for the alicyclic hydrocarbon group to be constituted from only the alicyclic structure, and a chain structure may be included in a part thereof. The “aromatic hydrocarbon group” as referred to herein means a hydrocarbon group having an aromatic ring structure as a ring structure, wherein it is not necessary for the aromatic hydrocarbon group to be constituted from only the aromatic ring structure, and a chain structure and/or an alicyclic structure may be included in a part thereof.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include:

alkyl groups such as a methyl group, an ethyl group, a n-propyl group, and an i-propyl group;

alkenyl groups such as an ethenyl group, a propenyl group, and a butenyl group;

alkynyl groups such as an ethynyl group, a propynyl group, and a butynyl group; and the like.

Examples of the monovalent alicyclic hydrocarbon group having 3 to 20 carbon atoms include:

monocyclic alicyclic saturated hydrocarbon groups such as a cyclopentyl group and a cyclohexyl group;

monocyclic alicyclic unsaturated hydrocarbon groups such as a cyclopentenyl group and a cyclohexenyl group;

polycyclic alicyclic saturated hydrocarbon groups such as a norbornyl group, an adamantyl group, and a tricyclodecyl group;

polycyclic alicyclic unsaturated hydrocarbon groups such as a norbornenyl group and a tricyclodecenyl group; and the like.

Examples of the monovalent aromatic hydrocarbon group having 6 to 20 carbon atoms include:

aryl groups such as a phenyl group, a tolyl group, a xylyl group, a naphthyl group, and an anthryl group;

aralkyl groups such as a benzyl group, a phenethyl group, a naphthylmethyl group, and an anthryl methyl group; and the like.

Examples of the hetero atom that constitutes the divalent or monovalent hetero atom-containing group include an oxygen atom, a nitrogen atom, a sulfur atom, a phosphorus atom, a silicon atom, a halogen atom, and the like.

Examples of the divalent hetero atom-containing group include —O—, —CO—, —S—, —CS—, —NR′—, groups obtained by combining two or more of these, and the like, wherein R′ represents a hydrogen atom or a monovalent chain hydrocarbon group. Of these, —O— or —S— is preferred, and —O— is more preferred.

The monovalent hetero atom-containing group is exemplified by a halogen atom, a hydroxy group, a carboxy group, a cyano group, an amino group, a sulfanyl group, and the like.

Examples of the ring structure having 3 to 20 ring atoms which may be represented by R^{A} and R^{B} taken together, together with the nitrogen atom to which R^{A} and R^{B} bond, include:

nitrogen-containing aliphatic heterocyclic structures such as an azacyclobutane structure, an azacyclopentane structure, an azacyclohexane structure, an azacyclopentene structure, and an azacyclohexene structure;

nitrogen-containing aromatic heterocyclic structures such as a pyrrole structure, a pyridine structure, an imidazole structure, a pyrimidine structure, a pyrazine structure, and a triazine structure; and the like.

R^{A} and R^{B} each represent preferably a monovalent hydrocarbon group or a hydrogen atom, more preferably a monovalent chain hydrocarbon group or a hydrogen atom, still more preferably an alkyl group, an alkenyl group, or a hydrogen atom, and particularly preferably a methyl group, an ethyl group, an allyl group, or a hydrogen atom.

—NR^{A}R^{B} which may be represented by Y¹ is preferably a dialkylamino group, an alkenylamino group, a dialkenylamino group, or a nitrogen-containing aromatic heterocyclic group, and more preferably a dimethylamino group, a diethylamino group, an allylamino group, a diallylamino group, or an imidazole group.

The divalent organic group having 1 to 20 carbon atoms which may be represented by R¹ is exemplified by a group derived by removing one hydrogen atom from the monovalent organic group having 1 to 20 carbon atoms exemplified for R^{A} and R^{B}, and the like.

Specific examples of the divalent organic group having 1 to 20 carbon atoms which may be represented by R¹ include

divalent hydrocarbon groups, e.g.:

alkanediyl groups such as a methanediyl group, an ethanediyl group, and a propanediylgroup;

divalent alicyclic hydrocarbon groups such as a cyclopentanediyl group and a cyclohexanediyl group;

arenediyl groups such as a benzenediyl group and a naphthalenediyl group; and

arenediylalkanediyl groups such as a benzenediylmethanediyl group and a benzenediylethanediyl group,

divalent carbonyloxyhydrocarbon groups, e.g., alkanediyloxycarbonyl groups such as an ethanediyloxycarbonyl group and a propanediyloxycarbonyl group,

divalent carbonylaminohydrocarbon groups, e.g., alkanediylaminocarbonyl groups such as an ethanediylaminocarbonyl group and a propanediylaminocarbonyl group,

divalent groups that each include an oxygen atom between two adjacent carbon atoms of the hydrocarbon group, e.g., arenediyloxyalkanediyl groups such as a benzenediyloxymethanediyl group and a benzenediyloxyethanediyl group, and the like.

The “divalent carbonyloxyhydrocarbon group” as referred to herein means a group represented by —C(═O)—O—Rx- (wherein RX represents a divalent hydrocarbon group). The “divalent carbonylaminohydrocarbon group” as referred to herein means a group represented by —C(═O)—NH—R^{Y}— (wherein R^{Y} represents a divalent hydrocarbon group).

In the case in which Y¹ represents —COOH, R¹ represents preferably the divalent hydrocarbon group or the divalent group that includes an oxygen atom between two adjacent carbon atoms of the hydrocarbon group, more preferably a divalent aromatic hydrocarbon group or a divalent group that includes an oxygen atom between two adjacent carbon atoms of the aromatic hydrocarbon group, still more preferably the arenediyl group or the arenediyloxyalkanediyl group, and particularly preferably a benzenediyl group or a benzenediyloxymethanediyl group.

In the case in which Y¹ represents —NR^{A}R^{B}, R¹ represents preferably the divalent hydrocarbon group, the divalent carbonylaminohydrocarbon group, or a single bond, more preferably a divalent chain hydrocarbon group, a divalent carbonylamino chain hydrocarbon group, or a single bond, still more preferably the alkanediyl group, the alkanediylaminocarbonyl group, or a single bond, and particularly preferably a methanediyl group or a propanediylaminocarbonyl group.

Examples of the compound (i) include compounds (hereinafter, may be also referred to as “compounds (i-1) to (i-15)”) represented by the following formulae (1-1) to (1-15), and the like.

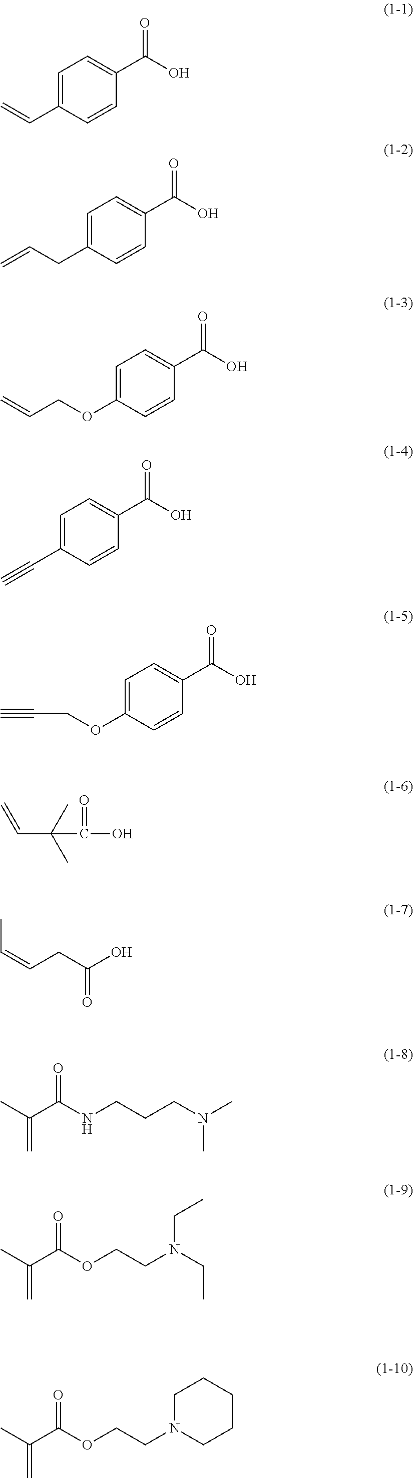

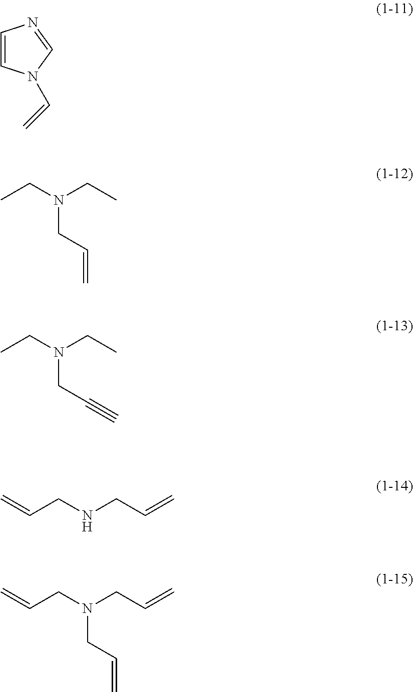

It is preferred that in the compound (i), the ethenyl group or the ethynyl group which may be represented by X¹ in the above formula (1) bonds to the carbon atom bonding to at least one hydrogen atom in R¹. In other words, in the compound (i), it is preferred that the ethenyl group or the ethynyl group which may be represented by X¹ in the above formula (1) bonds to —CHR′— (wherein R′ represents a hydrogen atom or a monovalent organic group having 1 to 20 carbon atoms) in R¹. In the case in which the compound (i) has such a structure, it is considered that the hydrogen atom bonding to the carbon atom adjacent to the ethenyl group or the ethynyl group which may be represented by X¹ becomes likely to be dissociated, thereby enabling a proton to be provided. As a result, the resolution and sensitivity can be further improved.

Examples of the compound (i) in which the ethenyl group or the ethynyl group which may be represented by X¹ bonds to the carbon atom bonding to at least one hydrogen atom in R¹ include compounds (i-2), (i-3), (i-5), (i-7), (i-12), (i-13), (i-14), (i-15), and the like.

Compound (ii)

The compound (ii) is represented by the following formula (2).

X²—CHR³—R²—Y² (2)

In the above formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.

The compound (ii) is exemplified by the carboxylic acid (X) in which Y² represents —COOH (hereinafter, may be also referred to as “carboxylic acid (ii-X)”), the nitrogen-containing compound (Z) in which Y² represents —N^{A}R^{B} (hereinafter, may be also referred to as “nitrogen-containing compound (ii-Z)”), and the like.

Examples of the monovalent halogenated hydrocarbon group having 1 to 20 carbon atoms which may be represented by X² include groups obtained by substituting with a halogen atom such as a fluorine atom, a chlorine atom, a bromine atom, or an iodine atom, a part or all of hydrogen atoms included in the group exemplified as the monovalent hydrocarbon group having 1 to 20 carbon atoms in R^{A} and R^{B} for Y¹ in the above formula (1), and the like.

Specific examples of the monovalent halogenated hydrocarbon group having 1 to 20 carbon atoms which may be represented by X² include:

halogenated alkyl groups such as a trifluoromethyl group, a chloromethyl group, a bromoethyl group, and an iodoethyl group;

halogenated aryl groups such as a fluorophenyl group, a chlorophenyl, a bromophenyl group, and an iodophenyl group; and the like.

The “oxyorganic group” as referred to herein means a group represented by —O—R^{Z} (wherein R^{Z} represents a monovalent organic group). The monovalent oxyorganic group having 1 to 20 carbon atoms which may be represented by X² is exemplified by a group obtained by combining an oxygen atom with the group exemplified as the monovalent organic group having 1 to 20 carbon atoms which may be represented by R^{A}or R^{B}.

Specific examples of the monovalent oxyorganic group having 1 to 20 carbon atoms which may be represented by X² include:

alkoxy groups such as a methoxy group and an ethoxy group;

cycloalkyloxy groups such as a cyclopentyloxy group and a cyclohexyloxy group;

aryloxy groups such as a phenoxy group and a naphthyloxy group; and the like.

Examples of the aryl group having 6 to 20 carbon atoms which may be represented by X² include:

a phenyl group, a naphthyl group, an anthryl group, a phenanthryl group, a tetracenyl group, a pyrenyl group, and the like.

The substituent for the aryl group which may be represented by X² is exemplified by a halogen atom, a hydroxy group, a cyano group, an alkoxy group, an acyl group, an acyloxy group, and the like.

Examples of the halogen atom which may be represented by X² include a fluorine atom, a chlorine atom, a bromine atom, an iodine atom, and the like.

Examples of —NR^{A}R^{B} which may be represented by Y² include groups similar to those exemplified as —NR^{A}R^{B} which may be represented by Y¹ described above, and the like.

—NR^{A}R^{B} which may be represented by Y² is preferably a dialkylamino group or a dialkenylamino group, and more preferably a diethylamino group or a diallylamino group.

Examples of the divalent organic group having 1 to 20 carbon atoms which may be represented by R² include groups similar to those exemplified as the divalent organic group having 1 to 20 carbon atoms which may be represented by R¹ described above, and the like.

In the case in which Y² represents —COOH, R² represents preferably the divalent hydrocarbon group or a divalent oxyhydrocarbon group, more preferably the divalent aromatic hydrocarbon group or a divalent oxyaromatic hydrocarbon group, still more preferably the arenediyl group or an arenediyloxy group, and particularly preferably a benzenediyl group or a benzenediyloxy group.

In the case in which Y² represents —NR^{A}R^{B}, R² represents preferably the divalent hydrocarbon group or a single bond, and more preferably a single bond.

The monovalent hydrocarbon group having 1 to 10 carbon atoms which may be represented by R³ is exemplified by groups having 1 to 10 carbon atoms among the monovalent hydrocarbon groups having 1 to 20 carbon atoms exemplified as R^{A} and R^{B} described above, and the like.

R³ represents preferably a hydrogen atom.

Examples of the compound (ii) include compounds (hereinafter, may be also referred to as “compounds (ii-1) to (ii-8)”) represented by the following formulae (2-1) to (2-8), and the like.

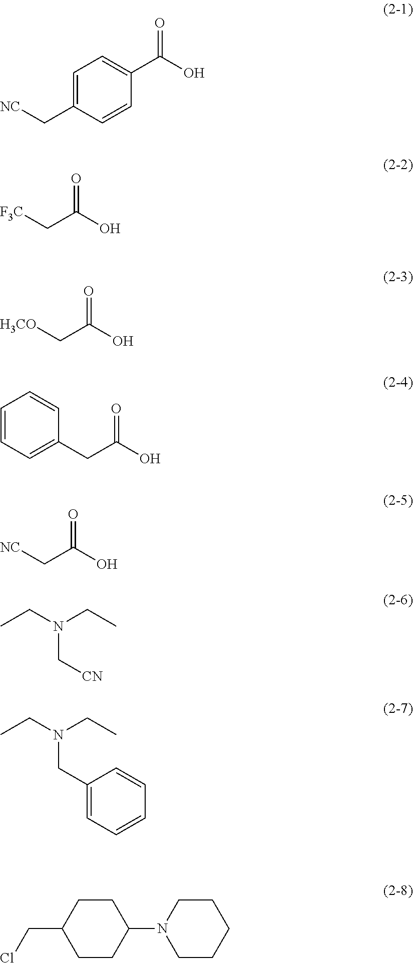

The compound (ii) is preferably the compound (ii-1) or (ii-6).

The compound (A1) has as the ligand (L), typically, a ligand (L-X) derived from the carboxylic acid (X) and/or a ligand (L-Z) derived from the nitrogen-containing compound (Z). In the compound (A1), at least one of the ligand (L-X) and the ligand (L-Z) is derived from the compound (S).

The compound (A1) may have a ligand (hereinafter, may be also referred to as “ligand (L′)”) other than the ligand (L). A compound that provides the ligand (L′) is exemplified by: the carboxylic acid (X) other than the compound (S); the nitrogen-containing compound (Z) other than the compound (S); and the like.

The number of the metal atom (M) in the compound (A1) may be one or more. The upper limit of the number of the metal atom (M) in the compound (A1) is preferably 30, more preferably 20, still more preferably 10, and particularly preferably 8.

In the case in which the compound (A1) has the ligand (L-X), the number of the ligand (L-X) is preferably 1 to 10, more preferably 1 to 5, still more preferably 1 to 3, and particularly preferably 1 or 2.

In the case in which the compound (A1) has the ligand (L-Z), the number of the ligand (L-Z) is preferably 1 to 10, more preferably 1 to 5, still more preferably 1 to 3, and particularly preferably 1 or 2.

It is preferred that the compound (A1) has both the ligand (L-X) and the ligand (L-Z).

The lower limit of a proportion of the metal atom (M) contained in the compound (A1) is preferably 3% by mass, more preferably 5% by mass, and still more preferably 10% by mass. The upper limit of the proportion of the metal atom (M) is preferably 90% by mass, more preferably 70% by mass, and still more preferably 50% by mass. When the proportion of the metal atom (M) falls within the above range, generation of secondary electrons by the compound (A1) can be further effectively promoted, and as a result, resolution and sensitivity of the composition (I) can be further improved.

The lower limit of a proportion of the ligand (L) contained in the compound (A1) is preferably 20% by mass, and more preferably 30% by mass. The upper limit of the proportion of the ligand (L) is preferably 80% by mass, and more preferably 70% by mass.

The lower limit of a proportion of the ligand (L-X) contained in the compound (A1) is preferably 10% by mass, and more preferably 20% by mass. The upper limit of the proportion of the ligand (L-X) is preferably 90% by mass, and more preferably 80% by mass.

The lower limit of a proportion of the ligand (L-Z) contained in the compound (A1) is preferably 10% by mass, and more preferably 20% by mass. The upper limit of the proportion of the ligand (L-Z) is preferably 90% by mass, and more preferably 80% by mass.

The lower limit of a proportion of the compound (A1) contained in all components other than the solvent (B) of the composition (I) is preferably 70% by mass, more preferably 80% by mass, and still more preferably 85% by mass. The proportion of the compound (A1) may be 100% by mass.

The lower limit of a proportion of the compound (A1) contained in the composition (I) is preferably 0.1% by mass, more preferably 1% by mass, and still more preferably 3% by mass. The upper limit of the proportion of the compound (A1) is preferably 30% by mass, more preferably 20% by mass, and still more preferably 10% by mass.

Synthesis Procedure of Compound (A1)

The compound (A1) can be synthesized by, for example, mixing the metal-containing compound (hereinafter, may be also referred to as “metal-containing compound (W)”) and the compound (S) that provides ligand (L), as well as a compound (other than the compound (S)) that provides a ligand included as needed, in an appropriate solvent.

The metal-containing compound (W) is exemplified by a metal oxoacid salt, a metal alkoxide, a metal halide, a metal oxide, a metal hydroxide, and the like.

Examples of the metal oxoacid salt include:

metal carboxylic acid salts such as a metal formate, a metal acetate, and a metal propionate;

metal sulfonic acid salts such as a metal methanesulfonate and a metal trifluoromethanesulfonate;

metal sulfuric acid salts; metal phosphoric acid salts; metal boric acid salts; and the like.

Examples of the metal alkoxide include a metal methoxide, a metal ethoxide, a metal propoxide, and the like.

Examples of the metal halide include a metal fluoride, a metal chloride, a metal bromide, a metal iodide, and the like.

Examples of the metal-containing compound (W) include a compound (hereinafter, may be also referred to as “metal-containing compound (W-1)”) represented by the following formula (A), and the like. When such a metal-containing compound (W-1) is used, the compound (A1) can be formed with more stability, and as a result, resolution and sensitivity of the composition (I) can be further improved.

LₐMY_{b} (A)

In the above formula (A), M represents the metal atom (M); L represents the ligand; a is an integer of 0 to 2, wherein in a case in which a is 2, a plurality of Ls are identical or different from each other; Y represents an oxoacid ion, an alkoxide ion or a halide ion; and b is an integer of 1 to 6, wherein in a case in which b is no less than 2, a plurality of Ys are identical or different from each other. It is to be noted that L is a ligand not falling under the categories of Y and the ligand (L).

The ligand represented by L is exemplified by: a 3-ketoenolate ligand derived from a β-dicarbonyl compound or the like; a hydrocarbon ligand derived from cyclopentadiene or the like; and the like.

Examples of the oxoacid ion which may be represented by Y include:

carboxylic acid ions such as a formate ion, an acetate ion, and a propionate ion;

sulfonic acid ions such as a methanesulfonate ion and a trifluoromethanesulfonate ion;

sulfuric acid ions; phosphoric acid ions; boric acid ions; and the like.

Examples of the alkoxide ion which may be represented by Y include a methoxide ion, an ethoxide ion, a propoxide ion, and the like.

Examples of the halide ion which may be represented by Y include a fluoride ion, chloride ion, a bromide ion, an iodide ion, and the like.

Y represents preferably the oxoacid ion or the alkoxide ion, more preferably the oxoacid ion, still more preferably the carboxylic acid ion, and particularly preferably an acetate ion.

In the above formula (A), a is preferably 0 or 1, and more preferably 0. In the above formula (A), b is preferably 1 to 4, and more preferably 1 or 2.

The metal-containing compound (W) is preferably the metal carboxylic acid salt, and more preferably the metal acetate.

Examples of the metal-containing compound (W) include:

metal carboxylic acid salts, e.g., metal acetates such as zinc(II) acetate, cobalt(II) acetate, and nickel(II) acetate;

metal alkoxides such as zinc(II) diisopropoxide, indium(III) triisopropoxide, titanium(IV) tetra-n-butoxide, zirconium(IV) tetra-n-butoxide, hafnium(IV) tetrabutoxide, tantalum(V) pentabutoxide, and tungsten(V) pentabutoxide;

metal halides such as iron(III) chloride, zinc(II) chloride, cobalt(II) bromide, and nickel(II) iodide; and the like.

Of these, the metal carboxylic acid salt is preferred, the metal acetate is more preferred, and zinc(II) acetate, cobalt(II) acetate or nickel(II) acetate is still more preferred.

In a case in which the compound (A1) has both the ligand (L-X) and the ligand (L-Z), the compound (A1) can typically be obtained by: dissolving the metal-containing compound (W) and the carboxylic acid (X) to prepare a solution: adding thereto the nitrogen-containing compound (Z) to allow for a reaction; and thereafter distilling off the solvent.

The solvent for use in the synthesis reaction of the compound (A1) is not particularly limited, and solvents similar to those exemplified in connection with the solvent (B) described later may be used. Of these, ester solvents are preferred, and ethyl acetate is more preferred.

The lower limit of a temperature of the synthesis reaction of the compound (A1) is preferably 0° C., and more preferably 10° C. The upper limit of the aforementioned temperature is preferably 150° C., and more preferably 100° C.

The lower limit of a time period of the synthesis reaction of the compound (A1) is preferably 1 min, more preferably 10 min, and still more preferably 1 hour. The upper limit of the time period is preferably 100 hrs, more preferably 50 hrs, and still more preferably 10 hrs.

In a case in which compound (A1) is in a particulate form, the upper limit of an average particle diameter of particles of the compound (A1) is preferably 20 nm, more preferably 15 nm, still more preferably 10 nm, particularly preferably 8 nm, further particularly preferably 5 nm, and most preferably 3 nm. The lower limit of the average particle diameter is preferably 0.3 nm, and more preferably 0.8 nm. When the average particle diameter of the compound (A1) falls within the above range, generation of secondary electrons by the compound (A1) can be further effectively promoted, and as a result, sensitivity can be further improved. The “average particle diameter” as referred to herein means a harmonic average particle diameter of based on scattered light intensity as measured by a DLS method.

### (B) Solvent

The organic solvent (B) is not particularly limited as long as it is a solvent capable of dissolving or dispersing at least the compound (A1), as well as optional component(s) which may be contained as needed. One, or two or more types of the organic solvent (B) may be used.

The solvent (B) is exemplified by alcohol solvents, ether solvents, ketone solvents, amide solvents, ester solvents, hydrocarbon solvents, and the like.

Examples of the alcohol solvent include: aliphatic monohydric alcohol solvents having 1 to 18 carbon atoms such as isopropyl alcohol, 4-methyl-2-pentanol, and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether; and the like.

Examples of the ether solvent include: dialkyl ether solvents such as diethyl ether, dipropyl ether, dibutyl ether, dipentyl ether, diisoamyl ether, dihexyl ether, and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone; cyclic ketone solvents such as cyclopentanone, cyclohexanone, cycloheptanone, cyclooctanone, and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:

monocarboxylic acid ester solvents such as ethyl acetate, n-butyl acetate, and ethyl lactate;

polyhydric alcohol carboxylate solvents such as propylene glycol acetate;

polyhydric alcohol partial ether carboxylate solvents such as propylene glycol monomethyl ether acetate (PGMEA);

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane, n-hexane, and decahydronaphthalene;

aromatic hydrocarbon solvents having 6 to 16 carbon atoms such as toluene and xylene; and the like.

Of these, the ester solvents are preferred, the polyhydric alcohol partial ether carboxylate solvents are more preferred, and PGMEA is still more preferred.

### (C) Acid Generating Agent

The acid generating agent (C) is a component that generates an acid by irradiation with a radioactive ray. The action of the acid generated from the acid generating agent (C) is able to further promote change of solubility, etc. in the developer solution of the compound (A1) in the composition (I), and as a result, the sensitivity and resolution can be further improved.

The acid generating agent (C) is exemplified by an onium salt compound, an N-sulfonyloxyimide compound, a halogen-containing compound, a diazo ketone compound, and the like.

Exemplary onium salt compounds include a sulfonium salt, a tetrahydrothiophenium salt, an iodonium salt, a phosphonium salt, a diazonium salt, a pyridinium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, 4-cyclohexylphenyldiphenylsulfonium nonafluoro-n-butanesulfonate, 4-methanesulfonylphenyldiphenylsulfonium nonafluoro-n-butanesulfonate, triphenylsulfonium 1,1,2,2-tetrafluoro-6-(1-adamantanecarbonyloxy)-hexane-1-sulfonate, triphenylsulfonium 2-(1-adamantyl)-1,1-difluoroethanesulfonate, triphenylsulfonium 2-(adamantan-1-ylcarbonyloxy)-1,1,3,3,3-pentafluoropropane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulfonate, 1-(6-n-butoxynaphthalen-2-yl)tetrahydrothiophenium nonafluoro-n-butanesulfonate, 1-(3,5-dimethyl-4-hydroxyphenyl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, bis(4-t-butylphenyl)iodonium nonafluoro-n-butanesulfonate, and the like.

Examples of the N-sulfonyloxyimide compound include N-(trifluoromethylsulfonyloxy)-1,8-naphthalimide, N-(trifluoromethylsulfonyloxy)bicyclo[2.2.1]hept-5-ene-2,3-dicarboxyimide, N-(nonafluoro-n-butylsulfonyloxy)bicyclo[2.2.1]hept-5-ene-2,3-dicarboxyimide, N-(perfluoro-n-octylsulfonyloxy)-1,8-naphthalimide, N-(perfluoro-n-octylsulfonyloxy)bicyclo[2.2.1]hept-5-ene-2,3-dicarboxyimide, N-(2-bicyclo[2.2.1]hept-²-yl-1,1,2,2-tetrafluoroethylsulfonyloxy)bicyclo[2.2.1]hept-5-ene-2,3-dicarboxyimide, N-(2-(3-tetracyclo[4.4.0.1^{2,5}1^{7,10}]dodecanyl)-1,1-difluoroethylsulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

Of these, the acid generating agent (C) is preferably the onium salt compound or the N-sulfonyloxyimide compound, more preferably the sulfonium salt or the N-sulfonyloxyimide compound, still more preferably a triphenylsulfonium salt, a 4-sulfonylphenyldiphenylsulfonium salt or an N-sulfonyloxyimide compound, and particularly preferably triphenylsulfonium trifluoromethanesulfonate, 4-cyclohexylsulfonylphenyldiphenylsulfonium 1,2-di(norbornanelactone-2-yloxycarbonyl)ethane-1-sulfonate or N-(trifluoromethylsulfonyloxy)-1,8-naphthalimide.

In a case in which the composition (I) contains the acid generating agent (C), the lower limit of the content of the acid generating agent (C) with respect to 100 parts by mass of the compound (A1) is preferably 1 part by mass, more preferably 4 parts by mass, and still more preferably 8 parts by mass. The upper limit of the content is preferably 40 parts by mass, more preferably 30 parts by mass, and still more preferably 20 parts by mass. When the content of the acid generating agent (C) falls within the above range, the resolution and sensitivity can be further improved. One, or two or more types of the acid generating agent (C) may be used.

### Other Optional Component(s)

The other optional component(s) is/are exemplified by a radical trapping agent, a radiation-sensitive radical-generating agent, an acid diffusion control agent, a surfactant, and the like. The composition (I) may contain one, or two or more types of the other optional component(s).

Radical Trapping Agent

The radical trapping agent is a compound capable of trapping a radical to inhibit a radical chain reaction. Exemplary radical trapping agents include a stable nitroxyl radical compound, a sulfide compound, a quinone compound, a phenol compound, an amine compound, a phosphite compound, and the like.

Examples of the stable nitroxyl radical compound include a piperidine-1-oxyl free radical, a 2,2,6,6-tetramethylpiperidine-1-oxyl free radical, a 4-oxo-2,2,6,6-tetramethylpiperidine-1-oxyl free radical, a 4-hydroxy-2,2,6,6-tetramethylpiperidine-1-oxyl free radical, a 4-acetamide-2,2,6,6-tetramethylpiperidine-1-oxyl free radical, a 4-maleimide-2,2,6,6-tetramethylpiperidine-1-oxyl free radical, a 4-phosphonoxy-2,2,6,6-tetramethylpiperidine-1-oxyl free radical, a 3-carboxy-2,2,5,5-tetramethylpyrrolidine-1-oxyl free radical, and the like.

Examples of the sulfide compound include phenothiazine, pentaerythritol-tetrakis(3-laurylthiopropionate), didodecyl sulfide, dioctadecyl sulfide, didodecyl thiodipropionate, dioctadecyl thiodipropionate, dimyristyl thiodipropionate, dodecyloctadecyl thiodipropionate, 2-mercaptobenzoimidazole, and the like.

Examples of the quinone compound include benzoquinone, 2,5-diphenyl-p-benzoquinone, p-toluquinone, p-xyloquinone, 2-hydroxy-1,4-naphthoquinone, and the like.

Examples of the phenol compound include hydroquinone, 4-methoxyphenol, 4-tert-butoxyphenol, catechol, 4-tert-butylcatechol, 2,5-di-tert-butylhydroquinone, 2,6-di-tert-butyl-4-methylphenol, 2,6-di-tert-butyl-m-cresol, pyrogallol, 2-naphthol, and the like.

Examples of the amine compound include N-(2,2,6,6-tetramethyl-4-piperidyl)dodecylsuccinimide, N,N′-bis(2,2,6,6-tetramethyl-4-piperidyl)butane tetracarboxylate, tetra(1,2,2,6,6-pentamethyl-4-piperidyl)butane tetracarboxylate, N,N′-di-sec-butyl-1,4-phenylenediamine, and the like.

Examples of the phosphite compound include triisodecyl phosphite, diphenyl-isodecyl phosphite, triphenyl phosphite, trinonylphenyl phosphite, and the like.

As the radical trapping agent, a high-molecular weight radical trapping agent such as, for example, “Chimassorb 2020” available from BASF SE or “ADK STAB LA-68” available from Adeka Corporation may be used aside from the compounds described above.

As the radical trapping agent, of these, the stable nitroxyl radical compound is preferred, and a 2,2,6,6-tetramethylpiperidine-1-oxyl free radical is more preferred.

In the case in which the composition (I) contains the radical trapping agent, the upper limit of the content of the radical trapping agent with respect to 100 parts by mass of the compound (A1) is preferably 0.01 parts by mass, more preferably 0.1 parts by mass, still more preferably 1 part by mass, and particularly preferably 2 parts by mass. The upper limit of the content is preferably 50 parts by mass, more preferably 20 parts by mass, still more preferably 15 parts by mass, and particularly preferably 10 parts by mass. When the content of the radical trapping agent falls within the above range, the resolution and sensitivity can be further improved.

Radiation-Sensitive Radical-Generating Agent

The radiation-sensitive radical-generating agent is a component that generates a radical by irradiation with a radioactive ray. As the radiation-sensitive radical-generating agent, a well-known compound may be used.

In the case in which the composition (I) contains the radiation-sensitive radical-generating agent, the content of the radiation-sensitive radical-generating agent may be variously predetermined within a range not leading to impairment of the effects of embodiments of the present invention.

Acid Diffusion Control Agent

The acid diffusion control agent controls a phenomenon of diffusion of the acid, which has been generated from the acid generating agent (C), etc. by the exposure, in the film, whereby an effect of inhibiting unwanted chemical reactions in an unexposed region is exhibited. In addition, storage stability of the composition (1) is further improved. Moreover, variation of the line width of the resist pattern caused by variation of post-exposure time delay from the exposure until a development treatment can be suppressed, which enables the radiation-sensitive resin composition with superior process stability to be obtained.

The acid diffusion control agent is exemplified by: a nitrogen atom-containing compound; a photolabile base that generates a weak acid by irradiation with a radioactive ray; and the like.

Examples of the nitrogen atom-containing compound include

monoamines, e.g., monoalkylamines such as n-hexylamine; dialkylamines such as di-n-butylamine; trialkylamines such as triethylamine; aromatic amines such as aniline; and the like,

diamines such as ethylenediamine and N,N,N′,N′-tetramethylethylenediamine,

polyamines such as polyethyleneimine and polyallylamine,

amine compounds of polymers of dimethylaminoethylacrylamide and the like,

amide group-containing compounds such as formamide and N-methylformamide,

urea compounds such as urea and methylurea,

pyridine compounds such as pyridine and 2-methylpyridine; morpholine compounds such as N-propylmorpholine and N-(undecylcarbonyloxyethyl)morpholine; nitrogen-containing heterocyclic compounds such as pyrazine and pyrazole,

nitrogen-containing heterocyclic compounds having an acid-labile group, such as N-t-butoxycarbonylpiperidine and N-t-butoxycarbonylimidazole; and the like.

The photolabile base is exemplified by an onium salt compound that loses acid diffusion controllability through degradation upon an exposure, and the like. Exemplary onium salt compounds include triphenylsulfonium salts, diphenyliodonium salts, and the like.

Examples of the photolabile base include triphenylsulfonium salicylate, triphenylsulfonium 10-camphorsulfonate, and the like.

In the case in which the composition (I) contains the acid diffusion control agent, the lower limit of the content of the acid diffusion control agent with respect to 100 parts by mass of the compound (A1) is preferably 0.1 parts by mass, more preferably 0.3 parts by mass, and still more preferably 1 part by mass. The upper limit of the content is preferably 20 parts by mass, more preferably 10 parts by mass, and still more preferably 5 parts by mass. When the content of the acid diffusion control agent falls within the above range, the resolution and sensitivity can be further improved.

Surfactant

The surfactant is a component that exhibits the effect of improving coating properties, striation and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of a commercially available product of the surfactant include KP341 (available from Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from Mitsubishi Materials Electronic Chemicals Co., Ltd.), Megaface F171 and Megaface F173 (each available from DIC Corporation), Fluorad FC430 and Fluorad FC431 (each available from 3M Japan Limited), ASAHI GUARD AG710, Surflon S-382, Surflon SC-101, Surflon SC-102, Surflon SC-103, Surflon SC-104, Surflon SC-105 and Surflon SC-106 (each available from AGC Inc.), and the like.

Preparation Procedure of Composition (I)

The composition (I) may be prepared, for example, by mixing the compound (A1) and the solvent (B), as well as the optional component(s) such as the acid generating agent (C) as needed, at a certain ratio, preferably followed by filtering a thus obtained mixture through a filter having a pore size of no greater than 0.2 μm. The lower limit of the solid content concentration of the composition (I) is preferably 0.1% by mass, more preferably 0.5% by mass, still more preferably 1% by mass, and particularly preferably 3% by mass. The upper limit of the solid content concentration is preferably 50% by mass, more preferably 30% by mass, still more preferably 15% by mass, and particularly preferably 7% by mass. The “solid content concentration” of the radiation-sensitive composition as referred to herein means a concentration (% by mass) of total components, other than the solvent (B), of the radiation-sensitive composition. Composition (II)

The composition (II) contains the compound (A2) and the solvent (B). The composition (II) may also contain, as a favorable component, the acid generating agent (C) described above, and may further contain the other optional component(s) described above within a range not leading to impairment of the effects of embodiments of the present invention.

Each component will be described in the following.

(A2) Compound

The compound (A2) is obtained by blending the metal-containing compound (W) and the organic compound (S).

Synthesis Procedure of Compound (A2)

The compound (A2) can be obtained by blending the metal-containing compound (W) and the organic compound (S). Specifically, the synthesis procedure is as described for the compound (A1) of the composition (I).

Examples of the metal-containing compound (W) include compounds similar to those of the metal-containing compound (W) used in the synthesis procedure of the compound (A1) in the composition (I), and the like.

Examples of the organic compound (S) include compounds similar to those of the compound (S) in the composition (I), and the like.

The solvent (B), the acid generating agent (C), the other optional component(s) and the like in the composition (II) are as described for the composition (I) above.

Preparation Procedure of Composition (II)

The composition (II) may be prepared, for example, by mixing the compound (A2) and the solvent (B) as well as the optional component(s) such as the acid generating agent (C) as needed, at a certain ratio, preferably followed by filtering a thus obtained mixture through a filter having a pore size of about 0.2 μm. The solid content concentration of the composition (II) is similar to the case of the composition (I) described above.

Composition (III)

The composition (III) contains the compound (S), the compound (W), and the solvent (B). The radiation-sensitive composition (III) may also contain, as a favorable component, the acid generating agent (C) described above, and may further contain the other optional component(s) described above within a range not leading to impairment of the effects of embodiments of the present invention.

It is considered that in the composition (III), a compound similar to the compound (A1) in the composition (I) is produced from: the compound (W) containing the metal atom; and the compound (S) that is equivalent to the compound (i) and/or the compound (ii).

Each component will be described in the following.

(S) Compound

The compound (S) is at least one selected from the group consisting of the compound (i) and the compound (ii). Examples of the compound (S) include compounds similar to those of the compound (S) in the composition (I), and the like.

(W) Compound

The compound (W) contains the metal atom. Examples of the compound (W) include compounds similar to the compounds exemplified as the metal-containing compound (W) in the composition (I), and the like.

The solvent (B), the acid generating agent (C), the other optional component(s) and the like in the composition (III) are as described for the compositions (I) and (II) above.

Preparation Procedure of Composition (III)

The composition (III) may be prepared, for example, by mixing the compound (S), the compound (W), and the solvent (B), as well as the other optional component(s) such as the acid generating agent (C) as needed, at a certain ratio, preferably followed by filtering a thus obtained mixture through a filter having a pore size of no greater than 0.2 m. The solid content concentration of the composition (III) is similar to the case of the composition (I) described above.

Pattern-Forming Method

The pattern-forming method according to an embodiment of the invention includes: applying the radiation-sensitive composition according to an embodiment of the invention directly or indirectly on a substrate (hereinafter, may be also referred to as “applying step”); exposing a film obtained by the applying step (hereinafter, may be also referred to as “exposing step”); and developing the film exposed (hereinafter, may be also referred to as “developing step”). Since the radiation-sensitive composition according to the embodiment of the invention described above is employed in the pattern-forming method, forming a pattern superior in resolution is enabled with high sensitivity.

Hereinafter, each step will be described.

Applying Step

In this step, the radiation-sensitive composition according to the embodiment of the invention is applied directly or indirectly on a substrate to form a film. Specifically, the film is formed by applying the radiation-sensitive composition to form a coating film such that the resulting film has a desired thickness, followed by prebaking (PB) to volatilize the organic solvent and the like in the coating film as needed. A procedure for applying the radiation-sensitive composition is not particularly limited, and an appropriate application procedure such as spin-coating, cast coating, roller coating, etc. may be employed. Examples of the substrate include a silicon wafer, a wafer coated with aluminum, and the like. It is to be noted that an organic or inorganic antireflective film may also be formed on the substrate in order to maximize potential of the radiation-sensitive composition.

The lower limit of an average thickness of the film to be formed in the present step is preferably 1 nm, more preferably 5 nm, still more preferably 10 nm, and particularly preferably 20 nm. Meanwhile, the upper limit of the average thickness is preferably 1,000 nm, more preferably 200 nm, still more preferably 100 nm, and particularly preferably 70 nm.

The lower limit of a temperature of the PB is preferably 30° C., more preferably 50° C., and still more preferably 70° C. The upper limit of the temperature of the PB is preferably 140° C., and more preferably 120° C. The lower limit of a time period of the PB is preferably 5 sec, and more preferably 10 sec. The upper limit of the time period of the PB is preferably 1 hour, more preferably 600 sec, and still more preferably 300 sec.

In this step, in order to inhibit an influence of basic impurities, etc., in the environmental atmosphere, for example, a protective film may be provided on the film formed. Furthermore, in the case of conducting liquid immersion lithography in the exposing step as described later, in order to avoid direct contact between a liquid immersion medium and the film, a protective film for liquid immersion may also be provided on the film formed.

Exposing Step

In this step, the film obtained by the applying is exposed. Specifically, for example, the film is irradiated with a radioactive ray through a mask having a predetermined pattern. In this step, irradiation with a radioactive ray through a liquid immersion medium such as water, i.e., liquid immersion lithography, may be employed as needed. Examples of the radioactive ray for the exposure include: electromagnetic waves e.g., ultraviolet rays such as visible light rays and KrF excimer laser beams (wavelength: 248 nm), far ultraviolet rays such as ArF excimer laser beams (wavelength: 193 nm), extreme ultraviolet rays (EUV; wavelength: 13.5 nm), X-rays, and γ-rays; charged particle rays such as electron beams (EB) and α-rays; and the like. Of these, in light of an increase of secondary electrons generated from the compound (A) having absorbed the radioactive ray, ultraviolet rays, far ultraviolet rays, extreme ultraviolet rays or electron beams are preferred, and extreme ultraviolet rays or electron beams are more preferred.

After the exposure, post exposure baking (PEB) may be also carried out. The lower limit of a temperature of the PEB is preferably 50° C., more preferably 70° C., and still more preferably 90° C. The upper limit of the temperature of the PEB is preferably 180° C., more preferably 140° C., and still more preferably 120° C. The lower limit of a time period of the PEB is preferably 5 sec, and more preferably 10 sec. The upper limit of the time period of the PEB is preferably 1 hour, more preferably 600 sec, and still more preferably 300 sec.

Developing Step

In this step, the film exposed is developed by using a developer solution. Accordingly, a predetermined pattern is formed. Examples of the developer solution include an alkaline aqueous solution, an organic solvent-containing liquid, and the like.

Examples of the alkaline aqueous solution include: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene and 1,5-diazabicyclo-[4.3.0]-5-nonene; and the like.

The lower limit of a content of the alkaline compound in the alkaline aqueous solution is preferably 0.1% by mass, more preferably 0.5% by mass, and further more preferably 1% by mass. The upper limit of the content of the alkaline compound is preferably 20% by mass, more preferably 10% by mass, and still more preferably 5% by mass.

As the alkaline aqueous solution, an aqueous TMAH solution is preferred, and a 2.38% by mass aqueous TMAH solution is more preferred.

Examples of an organic solvent in the organic solvent-containing liquid include organic solvents similar to those exemplified as the solvent (B) in the radiation-sensitive composition of the embodiment of the invention, and the like. Of these, the hydrocarbon solvent is preferred, and decahydronaphthalene is more preferred.

The lower limit of a content of the organic solvent in the organic solvent-containing liquid is preferably 80% by mass, more preferably 90% by mass, still more preferably 95% by mass, and particularly preferably 99% by mass. When the content of the organic solvent falls within the above range, further improvement of a contrast of the rate of dissolution in the developer solution between the light-exposed regions and the light-nonexposed regions is enabled. Examples of components other than the organic solvent in the organic solvent-containing liquid include water, silicone oil, and the like.

An appropriate amount of a surfactant may be added to the developer solution as needed. As the surfactant, for example, an ionic or nonionic fluorochemical surfactant, a silicone surfactant, and the like may be used.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate, which is rotated at a constant speed, while scanning with a developer solution-application nozzle at a constant speed; and the like.

It is preferred that, following the development, the substrate is rinsed by using a rinse agent such as water, alcohol, etc., and then dried. A procedure for the rinsing is exemplified by a procedure of continuously applying the rinse agent onto the substrate that is rotated at a constant speed (spin-coating procedure), a procedure of immersing the substrate for a given time period in the rinse agent charged in a container (dipping procedure), a procedure of spraying the rinse agent onto the surface of the substrate (spraying procedure), and the like.

### EXAMPLES

Hereinafter, the present invention is explained in detail by way of Examples, but the present invention is not in any way limited to these Examples.

### Synthesis of Compound (A)

The compound (A) was synthesized by the following procedure. The metal-containing compounds (W), the carboxylic acids (X) and the nitrogen-containing compounds (Z) used for the syntheses of the compounds (A) are as presented below.

(W) Metal-Containing Compound

Each composition formula is shown by the following formulae.

W-1: zinc(II) acetate dihydrate

W-2: cobalt(II) acetate tetrahydrate

W-3: nickel(II) acetate tetrahydrate

Zn(OAc)₂2H₂O (W-1)

Co(OAc)₂4H₂O (W-2)

Ni(OAc)₂4H₂O(W-3)

(X) Carboxylic Acid

Each structural formula is shown below.

X-1: m-toluic acid

X-2: 4-vinylbenzoic acid

X-3: 4-cyanomethylbenzoic acid

X-4: 4-allyloxybenzoic acid

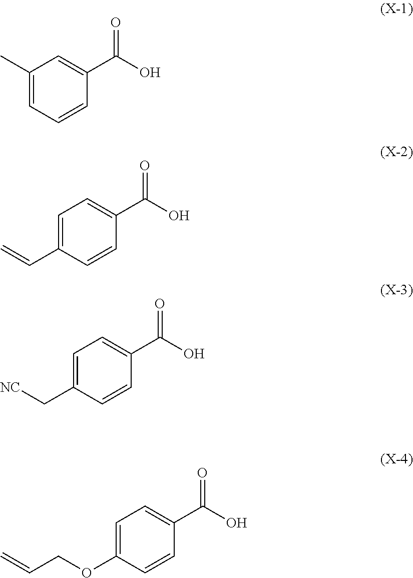

(Z) Nitrogen-Containing Compound

Each structural formula is as presented below.

Z-1: triethylamine

Z-2: N-(3-dimethylamino propyl)methacrylamide

Z-3: diethylaminoacetonitrile

Z-4: diethylallylamine

Z-5: diethylpropargylamine

Z-6: triallylamine

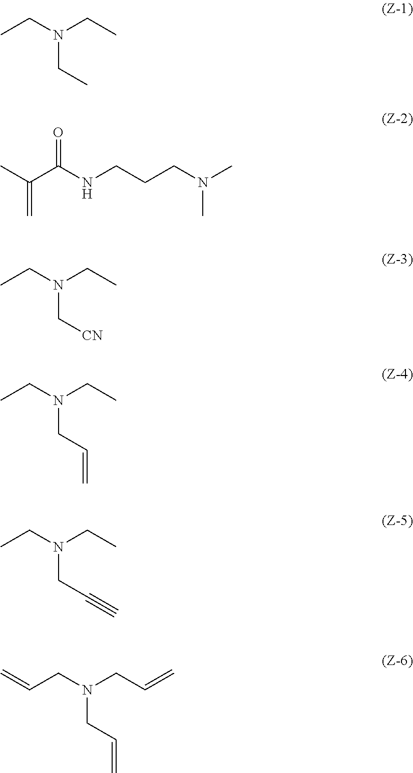

### Synthesis Example 1

The compound (W-1) in an amount of 1.7 g and the compound (X-1) in an amount of 1.9 g were dissolved in 40.0 g of ethyl acetate. To this solution, 2.2 mL of the compound (Z-1) was added dropwise, and the mixture was heated at 65° C. for 10 hrs. Ethyl acetate was distilled off by vacuum concentration to give a compound (A-1) having a metal atom, a carboxylic acid, and a ligand derived from a nitrogen-containing compound.

### Synthesis Examples 2 to 11

Compounds (A-2) to (A-11) were obtained by a similar operation to Synthesis Example 1 except that the type and the amount of each compound used were as shown in Table 1 below.

TABLE 1

| | | (W) Metal- | | | | (Z) Nitrogen- | |
|---|---|---|---|---|---|---|---|
| | | containing | | (X) Carboxylic | | containing | |
| | | compound | | acid | | compound | |
| | (A) | | mass | | mass | | volume |
| | Compound | type | (g) | type | (g) | type | (mL) |
| Synthesis | A-1 | W-1 | 1.7 | X-1 | 1.9 | Z-1 | 2.2 |
| Example 1 | | | | | | | |
| Synthesis | A-2 | W-1 | 1.7 | X-1 | 1.9 | Z-2 | 2.8 |
| Example 2 | | | | | | | |
| Synthesis | A-3 | W-1 | 1.7 | X-2 | 2.1 | Z-1 | 2.2 |
| Example 3 | | | | | | | |
| Synthesis | A-4 | W-1 | 1.7 | X-1 | 1.9 | Z-3 | 2.0 |
| Example 4 | | | | | | | |
| Synthesis | A-5 | W-1 | 1.7 | X-3 | 2.2 | Z-1 | 2.2 |
| Example 5 | | | | | | | |
| Synthesis | A-6 | W-1 | 1.7 | X-1 | 1.9 | Z-4 | 2.4 |
| Example 6 | | | | | | | |
| Synthesis | A-7 | W-1 | 1.7 | X-1 | 1.9 | Z-5 | 2.2 |
| Example 7 | | | | | | | |
| Synthesis | A-8 | W-1 | 1.7 | X-1 | 1.9 | Z-6 | 2.7 |
| Example 8 | | | | | | | |
| Synthesis | A-9 | W-2 | 1.7 | X-4 | 2.5 | Z-1 | 2.2 |
| Example 9 | | | | | | | |
| Synthesis | A-10 | W-2 | 1.9 | X-1 | 1.9 | Z-6 | 2.7 |
| Example 10 | | | | | | | |
| Synthesis | A-11 | W-3 | 1.9 | X-1 | 1.9 | Z-6 | 2.7 |
| Example 11 | | | | | | | |

### Preparation of Radiation-Sensitive Composition

The solvent (B) and the acid generating agents (C) which were used in the preparation of the radiation-sensitive composition are as presented below.

(B) Solvent

A structural formula is shown below.

B-1 propylene glycol monomethyl ether acetate

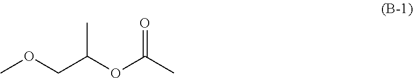

(C) Acid Generating Agent

Each structural formula is shown below.

C-1: N-(trifluoromethylsulfonyloxy)-1,8-naphthalimide

C-2: triphenylsulfonium trifluoromethanesulfonate

C-3: 4-cyclohexylsulfonylphenyldiphenylsulfonium 1,2-di(norbornanelactone-2-yloxycarbonyl)ethane-1-sulfonate

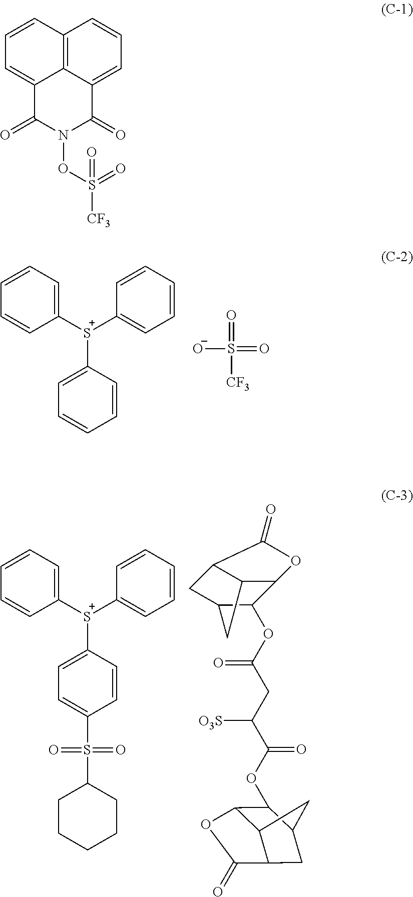

### Comparative Example 1-1

A mixed liquid having a solid content concentration of 5% by mass was provided by mixing 100 parts by mass of (A-1) as the compound (A), 10 parts by mass of (C-1) as the acid generating agent (C), and (B-1) as the solvent (B). A mixed liquid thus obtained was filtered through a membrane filter having a pore size of 0.20 μm to prepare a radiation-sensitive composition (R-1).

### Examples 1-1 to 1-12

Radiation-sensitive compositions (R-2) to (R-13) were prepared by a similar operation to Comparative Example 1-1 except that the type and the content of each component used were as shown in Table 2 below.

TABLE 2

| | | | | | (C) Acid | |
|---|---|---|---|---|---|---|
| | | (A) Compound | | | generating agent | |
| | Radiation- | | content | (B) | | content |
| | sensitive | | (parts by | Solvent | | (parts by |
| | composition | type | mass) | type | type | mass) |
| Comparative | R-1 | A-1 | 100 | B-1 | C-1 | 10 |
| Example 1-1 | | | | | | |
| Example 1-1 | R-2 | A-2 | 100 | B-1 | C-1 | 10 |
| Example 1-2 | R-3 | A-3 | 100 | B-1 | C-1 | 10 |
| Example 1-3 | R-4 | A-4 | 100 | B-1 | C-1 | 10 |
| Example 1-4 | R-5 | A-5 | 100 | B-1 | C-1 | 10 |
| Example 1-5 | R-6 | A-6 | 100 | B-1 | C-1 | 10 |
| Example 1-6 | R-7 | A-7 | 100 | B-1 | C-1 | 10 |
| Example 1-7 | R-8 | A-8 | 100 | B-1 | C-1 | 10 |
| Example 1-8 | R-9 | A-9 | 100 | B-1 | C-1 | 10 |
| Example 1-9 | R-10 | A-10 | 100 | B-1 | C-1 | 10 |
| Example 1-10 | R-11 | A-11 | 100 | B-1 | C-1 | 10 |
| Example 1-11 | R-12 | A-9 | 100 | B-1 | C-2 | 10 |
| Example 1-12 | R-13 | A-9 | 100 | B-1 | C-3 | 10 |

### Pattern Formation

### Comparative Example 2-1

The radiation-sensitive composition (R-1) prepared in Comparative Example 1-1 described above was spin-coated onto a silicon wafer by a simplified spin coater, and subjected to PB at 100° C. for 60 sec to form a film having an average thickness of 50 nm. Next, the film was exposed to an electron beam using an electron beam writer (“JBX-9500FS” available from JEOL, Ltd.) and subjected to PEB at 100° C. for 60 sec to permit patterning. Subsequent to the exposure to the electron beam, the film was developed with decahydronaphthalene and then dried to form a negative-tone pattern.

### Examples 2-1 to 2-12

Each pattern was formed by a similar operation to Comparative Example 2-1 except that each radiation-sensitive composition shown in Table 3 below was used and that the temperature of the PB and the temperature of PEB were as shown in Table 3.

### Evaluations

Each radiation-sensitive composition prepared and each pattern formed as described above were evaluated with respect to a limiting resolution and sensitivity by the following methods. The results of the evaluations are shown in Table 3.

Limiting Resolution

Line and space patterns (1L 1S) were produced to have various line widths, and a half-pitch of the pattern in which a total of the line widths and the space widths was the smallest among the line and space patterns having the line width of 1:1 being maintained was defined as the limiting resolution (nm). A smaller limiting resolution value indicates superior resolution.

Sensitivity

An exposure dose at which a line-and-space pattern (1L 1S) with a line width of 1:1 was formed, the pattern being configured with: line parts each having a line width of 100 nm; and space parts formed between adjacent line parts, each being an interval of 100 nm, was defined as “optimal exposure dose”, and the “optimal exposure dose” was defined as “sensitivity” (μC/cm²). A smaller sensitivity value indicates superior sensitivity.

TABLE 3

| | | PB | PEB | | |
|---|---|---|---|---|---|
| | Radiation- | temper- | temper- | limiting | |
| | sensitive | ature | ature | resolution | Sensitivity |
| | composition | (° C.) | (° C.) | (nm) | (μC/cm²) |
| Comparative | R-1 | 100 | 100 | 45 | 65 |
| Example 2-1 | | | | | |
| Example 2-1 | R-2 | 100 | 100 | 40 | 55 |
| Example 2-2 | R-3 | 100 | 100 | 40 | 50 |
| Example 2-3 | R-4 | 100 | 100 | 35 | 60 |
| Example 2-4 | R-5 | 100 | 100 | 35 | 55 |
| Example 2-5 | R-6 | 100 | 100 | 30 | 50 |
| Example 2-6 | R-7 | 100 | 100 | 30 | 45 |
| Example 2-7 | R-8 | 100 | 100 | 25 | 50 |
| Example 2-8 | R-9 | 100 | 100 | 25 | 45 |
| Example 2-9 | R-10 | 100 | 100 | 25 | 40 |
| Example 2-10 | R-11 | 100 | 100 | 25 | 40 |
| Example 2-11 | R-12 | 100 | 100 | 25 | 40 |
| Example 2-12 | R-13 | 100 | 100 | 25 | 45 |

As is seen from the results shown in Table 3, the radiation-sensitive compositions of the Examples enable a pattern having high resolution to be formed with high sensitivity. In general, a tendency similar to the case of an exposure to an extreme ultraviolet ray has been known to be exhibited by an exposure to an electron beam. Therefore, from the results of the present Examples, it is speculated that a pattern having high resolution can be formed with high sensitivity also in the case of the exposure to the extreme ultraviolet ray.

The radiation-sensitive composition and the pattern-forming method of the embodiments of the present invention enable a pattern having high resolution to be formed with high sensitivity. The compound of the embodiment of the present invention can be suitably used as a component of the radiation-sensitive composition. Therefore, these can be suitably used for formation of fine resist patterns in lithography steps of various types of electronic devices such as semiconductor devices and liquid crystal devices for which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive composition, comprising:
a compound comprising a metal atom and a ligand; and
a solvent,
wherein the ligand is derived from a first compound represented by formula (1), a second compound represented by formula (2), or a combination thereof,
X¹—R¹—Y¹ (1)
X²—CHR³—R²—Y² (2)
wherein,
in the formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; and R¹ represents a single bond or a divalent organic group having 1 to 20 carbon atoms in a case in which Y¹ represents —NR^{A}R^{B}, or R¹ represents a divalent organic group having 1 to 20 carbon atoms in a case in which Y¹ represents —COOH, and
in the formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.

2. A radiation-sensitive composition, comprising:
a compound obtained by blending a metal-containing compound and an organic compound; and
a solvent,
wherein the organic compound is a first compound represented by formula (1), a second compound represented by formula (2), or a combination thereof,
X¹—R¹—Y¹ (1)
X²—CHR³—R²—Y² (2)
wherein,
in the formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; and R¹ represents a single bond or a divalent organic group having 1 to 20 carbon atoms in a case in which Y¹ represents —NR^{A}R^{B}, or R¹ represents a divalent organic group having 1 to 20 carbon atoms in a case in which Y¹ represents —COOH, and
in the formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.

3. A radiation-sensitive composition, comprising:
a first compound represented by formula (1), a second compound represented by formula (2), or a combination thereof;
a compound comprising a metal atom; and
a solvent,
X¹—R¹—Y¹ (1)
X²—CHR³—R²—Y² (2)
wherein,
in the formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; and R¹ represents a single bond or a divalent organic group having 1 to 20 carbon atoms in a case in which Y¹ represents —NR^{A}R^{B}, or R¹ represents a divalent organic group having 1 to 20 carbon atoms in a case in which Y¹ represents —COOH, and
in the formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.

4. The radiation-sensitive composition according to claim 1, further comprising:
a radiation-sensitive acid generating agent.

5. The radiation-sensitive composition according to claim 2, further comprising:
a radiation-sensitive acid generating agent.

6. The radiation-sensitive composition according to claim 3, further comprising:
a radiation-sensitive acid generating agent.

7. A pattern-forming method, comprising:
applying the radiation-sensitive composition of claim 1 directly or indirectly on a substrate;
exposing a film formed by the applying; and
developing the film exposed.

8. A pattern-forming method, comprising:
applying the radiation-sensitive composition of claim 2 directly or indirectly on a substrate;
exposing a film formed by the applying; and
developing the film exposed.

9. A pattern-forming method, comprising:
applying the radiation-sensitive composition of claim 3 directly or indirectly on a substrate;
exposing a film formed by the applying; and
developing the film exposed.

10. A compound, comprising:
a metal atom; and
a ligand derived from a first compound represented by formula (1), a second compound represented by formula (2), or a combination thereof,
X¹—R¹—Y¹ (1)
X²—CHR³—R²—Y² (2)
wherein,
in the formula (1), X¹ represents a substituted or unsubstituted ethenyl group or a substituted or unsubstituted ethynyl group; Y¹ represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; and R¹ represents a single bond or a divalent organic group having 1 to 20 carbon atoms in a case in which Y¹ represents —NR^{A}R^{B}, or R¹ represents a divalent organic group having 1 to 20 carbon atoms in a case in which Y¹ represents —COOH, and
in the formula (2), X² represents a monovalent halogenated hydrocarbon group having 1 to 20 carbon atoms, a monovalent oxyorganic group having 1 to 20 carbon atoms, a substituted or unsubstituted aryl group having 6 to 20 carbon atoms, a cyano group, or a halogen atom; Y² represents —NR^{A}R^{B} or —COOH, wherein R^{A} and R^{B} each independently represent a hydrogen atom or a monovalent organic group having 1 to 20 carbon atoms, or R^{A} and R^{B} taken together represent a part of a ring structure having 3 to 20 ring atoms together with the nitrogen atom to which R^{A} and R^{B} bond; R² represents a single bond or a divalent organic group having 1 to 20 carbon atoms; and R³ represents a hydrogen atom or a monovalent hydrocarbon group having 1 to 10 carbon atoms.
